(19) United States
(12) Patent Application Publication
(10) Pub. No.: US 2010/0089620 A1
(43) Pub. Date: Apr. 15, 2010

(54) Electronic Component Module and Method for the Production Thereof

(76) Inventors: Richard Matz, Bruckmuhl (DE); Ruth Männer, Oberpframmern (DE); Steffen Walter, Oberpframmern (DE)

Correspondence Address: COHEN, PONTANI, LIEBERMAN & PAVANE LLP, 551 FIFTH AVENUE, SUITE 1210, NEW YORK, NY, 10176, US

(21) Appl. No.: 12/517,168

(22) PCT Filed: Nov. 30, 2006
(86) PCT No.: PCT/EP06/69126

§ 371 Date: Jun. 1, 2009

(51) Int. Cl. H05K 7/20; H05K 3/00; H05K 3/16; H05K 3/06

(52) U.S. Cl. 174/252; 29/825; 427/99.2; 216/13; 204/192.15; 204/192.3

(57) ABSTRACT

An electronic component module comprising: at least one multilayer ceramic circuit carrier (2, 3); at least one cooling device comprising at least one heat sink; a composite layer (5, 6) arranged at least in regions between the ceramic circuit carrier (2, 3) and the cooling device (4), said composite layer being formed for reactive connection to the ceramic circuit carrier (2, 3) during a primary process and for connection to the cooling device (4).

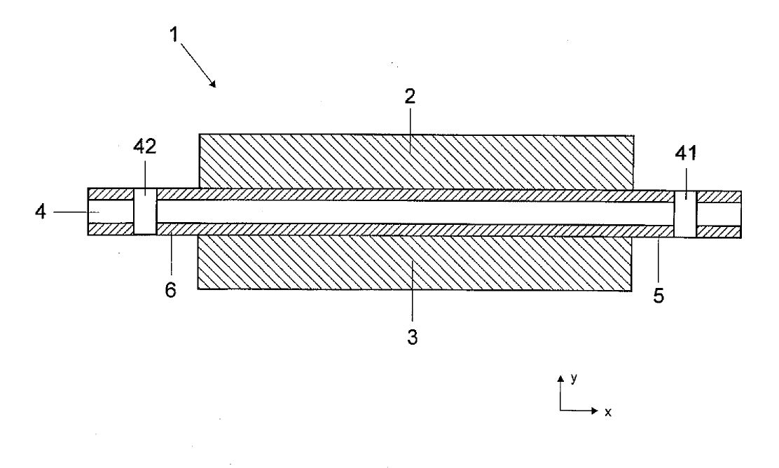

### TECHNICAL FIELD

The invention relates to an electronic component module comprising at least one multilayer circuit carrier and a cooling device comprising at least one heat sink. Furthermore, the invention also relates to a method for producing an electronic component module of this type.

### PRIOR ART

Electronic component modules comprising a plurality of multilayer circuit carriers are known. These are manufactured for example by LTCC (Low Temperature Cofired Ceramics), which represents a high-performance technology for producing ceramic circuit carriers from a plurality of individual layers. For this purpose, ceramic unsintered green films, for the electrical plated-through, holes, are provided with openings by stamping-out, the openings are filled with electrically conductive paste and the films are provided with planar line structures on their surface in the screen printing method. A large number of these individual layers can finally be laminated onto one another and sintered at a relatively low temperature. The process yields multilayer buried layout structures which can be utilized for the integration of passive circuit elements. Moreover, it is thereby possible to create layout structures which have very good radiofrequency properties, are hermetically sealed and have good thermal stability.

With these properties, LTCC technology is suitable for applications in adverse surroundings, for example for sensors, in radiofrequency technology, for example in mobile radio and the field of radar, and in power electronics, for example in vehicle electronics, transmission and engine control. Thermally demanding applications are often limited, however, by relatively poor thermal conductivity of the material, which typically has a thermal conductivity of 2 W/m K. For the cooling of active semiconductor components that are part of such LTCC modules in general as surface mounted devices, merely mounting the LTCC substrate on a heat sink does not suffice. In particular, soldering or adhesively bonding an LTCC substrate onto a heat sink, as is described in J. Schulz-Harder et al.: “Micro channel water cooled power modules”, pages 1 to 6, PCIM 2000 Nürnberg, does not suffice.

An LTCC ceramic is compatible with silver metallization in the standard process. One conventional solution for LTCC substrates is therefore the integration of thermal vias. These are vertical plated-through holes which are filled with silver-filled conductive paste and primarily serve for heat dissipation. An average thermal conductivity of 20 W/m K can be achieved in this way. In combination with silver-filled films, values of 90 W/m K and 150 W/m K were made possible in the vertical and horizontal directions, respectively. This is disclosed by M. A. Zampino et al.: “LTCC substrates with internal cooling channel and heat exchanger”, Proc. Internat. Symp. on Microelectronics 2003, Internat. Microelectronics and Packaging Society (IMAPS), 18-20 Nov. 2003, Boston, USA.

A further solution is the mounting of semiconductor ICs (integrated circuits) having a high heat loss, for example power amplifiers, in cutouts of the LTCC circuit board directly on the heat sink.

Furthermore, solutions are known what are based on the integration of liquid-filled channels. In this case, the cooling is effected by convection of a liquid having a high heat capacity, for example water, as is described in the abovementioned prior art in accordance with J. Schulz-Harder et al.: “Micro channel water cooled power modules”, and furthermore in M. A. Zampino et al.: “Embedded heat pipes with MCM-C Technology”, Proc. NEPCON West 1998 Conference Vol. 2, Reed Exhibition Norwalk, Conn. USA 1998, pages 777-785, Vol. 2, (Conf. Anaheim, USA, 1-5 Mar. 1998).

A solution based thereon does not utilize the heat capacity of the cooling liquid for the heat transfer, but rather the latent heat of a phase transition. This is described in the abovementioned prior art in accordance with M. A. Zampino et al.: “LTCC substrates with internal cooling channel and heat exchanger” and in W. K. Jones et al.: “Thermal management in low temperature cofire ceramic (LTCC) using high density thermal vias and micro heat pipes/spreaders”, Proc. Internat. Symp. on Microelectronics 2002, Internat. Microelectronics and Packaging Society (IMAPS), 10-13 Mar. 2002, Reno, USA. The “heat pipes” explained therein are used according to the prior art for example for the cooling of processors in compact computers such as laptops, for example.

Besides these methods suitable for LTCC, for highly sintering aluminum oxide ceramic the so-called direct copper bonding process is suitable and widespread for connecting circuit carriers composed of sintered aluminum oxide directly to cooling films composed of copper at approximately 1100° C. This is described in J. Schulz-Harder et al.: “Micro channel water cooled power modules” and J. Schulz-Harder et al.: “DBC substrate with integrated flat heat pipe”, EMPC 2005, The 15th European Microelectronics and Packaging Conference Exhibition, 12-15 Jun. 2005, Bruges, Belgium.

### SUMMARY OF THE INVENTION

The invention is based on the object of providing an electronic component module and a method for producing an electronic component module of this type wherein highly thermally conductive substrates can be stably connected to a multilayer circuit carrier in a simple manner and with little outlay and the heat dissipation can be improved.

This object is achieved by means of an electronic component module having the features according to patent claim 1, and a method having the features according to patent claim 12.

An electronic component module according to the invention comprises at least one multilayer ceramic circuit carrier and a cooling device comprising at least one heat sink. At least one composite layer is arranged at least in regions between the ceramic circuit carrier and the cooling device, said at least one composite layer being formed for reactive connection, in particular for LTCC-reactive connection, to the ceramic circuit carrier during a primary process and for connection to the cooling device. By means of said composite layer and in particular the configuration thereof, it is possible to achieve a stable connection between the components of the component module. Furthermore, the composite layer can be produced with little outlay since it combines reactively with the ceramic circuit carrier. Consequently, the connection of the circuit carrier to said composite layer can be produced automatically in particular during the actual process of joining together the ceramic circuit carrier with the cooling device. Owing to its material embodiment, the composite layer can be reactively connected to the circuit carrier stably during a primary process. A primary process is understood to mean a process which is carried out primarily for a different bond production between components of the component module. In particular, this bond can be reactively produced automatically in an LTCC process. A separate downstream method step such as is the case as a result of non-reactive connection such as with soldering or adhesive bonding no longer has to be carried out here. Consequently, reactive connection is understood to mean all processes which produce a dual effect. Firstly the primary effect as a result of the process and secondly the connection of the composite layer to the circuit carrier. In a preferred LTCC process, the dual effect is afforded by the fact that firstly the individual layers of the circuit carrier can be connected and, in addition, according to the invention, the reactive bond between the composite layer and the circuit carrier can be formed.

Particularly when the circuit carrier is formed as an LTCC circuit carrier, the composite layer is formed as a reactive coating suitable for LTCC. In this configuration, what can then also be achieved in the actual LTCC process is that the ceramic circuit carrier is automatically connected to the composite layer in a mechanically stable manner. Furthermore, the mechanically stable connection to the cooling device is also ensured.

Consequently, the reactive connection can be effected under the customary process conditions in an LTCC process for applying the circuit carrier to the cooling device.

Preferably, the composite layer is formed over the whole area between the circuit carrier and the cooling device. This enables a particularly effective fixing and furthermore also an optimum heat dissipation.

Preferably, the cooling device is formed for lateral heat dissipation and the heat sink extends laterally beyond the dimensions of the circuit carrier at least at one side. The lateral cooling concept makes it possible to form a more compact electronic component module which nevertheless enables an improved heat dissipation.

It is particularly preferred if the circuit carrier is formed as a ceramic LTCC circuit carrier and the composite layer, for reactively producing a bond with the circuit carrier, is formed or can be produced during the LTCC process for forming the ceramic circuit carrier. What can be achieved by this configuration is that the connection can be produced automatically in practice during the LTCC method wherein the individual layers are laminated onto one another and are sintered at a corresponding temperature. Consequently, as an essential advantage over the prior art, the connection does not have to be produced in a further manufacturing method downstream of the LTCC process, for example by means of hard soldering, rather said connection can be effected essentially simultaneously with, or overlapping at least at times, the connecting production of the individual layers of the circuit carrier.

The composite layer is preferably formed at least as a monolayer, component-free and electrically line-free LTCC film. In this configuration, the composite layer is therefore provided as an intermediate film. In particular, it can then be provided that the composite layer with an in particular individual intermediate film is fitted in a sintering process under adapted conditions, in particular concerning the gas atmosphere and the temperature profile. In particular, provision is made here for applying said intermediate film to the cooling device.

The composite layer can also be formed at least proportionally from glass.

It can likewise be provided that the composite layer is formed at least proportionally from nanocrystalline material, in particular nanocrystalline aluminum oxide. It can likewise be provided that the composite layer is formed at least proportionally from a ceramic material, in particular silicon oxide and/or silicon nitride.

The composite layer can be formed at least proportionally from a reactive metal, in particular from titanium.

It proves to be particularly preferred if the bond between the circuit carrier and the composite layer is formed by a sintering process at a temperature of between 840° C. and 930° C., in particular at approximately 900° C. With these process conditions it is also possible to ensure an optimum formation of the ceramic circuit carrier and in particular the bond between the individual layers. At the same time, the reactive bond between the composite layer and the circuit carrier can also be made possible with these optimized process conditions.

In a method according to the invention for producing an electronic component module, at least one ceramic multilayer circuit carrier is connected to at least one cooling device comprising at least one heat sink. A composite layer for connecting the components is formed at least in regions between the ceramic circuit carrier and the cooling device. The composite layer is reactively connected to the circuit carrier during the process of connecting the individual layers of the circuit carrier. This production method can provide a significantly improved composite structure which can be realized with significantly less outlay in terms of production engineering.

It proves to be particularly preferred if the circuit carrier is formed as a ceramic LTCC circuit carrier and the composite layer is connected to the circuit carrier during the LTCC process. The heat sink-ceramic composite can thereby be obtained at relatively low temperatures, the cooling device preferably being provided with a reactive composite layer suitable for LTCC in an upstream process step for the configuration of the electronic component module. Afterward, the LTCC multilayer and hence the LTCC circuit carrier is then applied to the prepared surface, in particular by sintering, under corresponding process conditions.

Advantageously, at least one monolayer, component-free and line-free (without electrical lines) and also electrically insulating LTCC film as an intermediate film in the form of a gradient film is formed as the composite layer. In this case, it is preferably provided that the intermediate film is applied in a sintering process under adapted conditions. In this case, it can be provided that this is effected under a nitrogen atmosphere with addition of argon. This procedure enables the process parameters to be adapted, for example in order to obtain an optimum metal-ceramic composite, without consideration of the standard conditions for the connection of the individual layers of the circuit carrier, and in particular the standard conditions of LTCC technology. These standard conditions of LTCC technology are determined by the presence of line structures composed of silver-containing screen printing paste. In particular, the gas atmosphere is in this case characterized by oxygen or air.

The functional LTCC films of the multilayer circuit carrier which have electronic devices and integrated line structures are laminated onto the intermediate film. In order to avoid the xy shrinkage of the functional layers, it is preferably the case that in addition a sacrificial film composed of aluminum oxide (Al₂O₃) is laminated onto the top side of the circuit carrier and finally sintered in the so-called zero-shrinkage method.

Furthermore, it can be provided that the composite layer is formed at least proportionally from glass, is applied in particular by screen printing and is subsequently thermally treated. This configuration also enables an optimum composite structure during the process of connecting the individual layers of the circuit carrier.

It can also be provided that the composite layer is applied at least proportionally from nanocrystalline material, in particular is applied by a screen printing method. Nanocrystalline aluminum oxide, in particular, is provided as the nanocrystalline material. Since the sintering temperature decreases as the grain size decreases, nanocrystalline material opens up an LTCC-compatible process path.

Furthermore, the composite layer can also be formed at least proportionally from a ceramic material, in particular from silicon oxide and/or silicon nitride. In this configuration, it can be provided that said ceramic material is applied by a sputtering method, in particular is sputtered onto the cooling device. The ceramic layers deposited by physical low-temperature methods serve as adhesion layers for the LTCC ceramic applied later.

Furthermore, the composite layer can also be formed at least proportionally by a coating with reactive metals, in particular titanium. These reactive metals should be regarded as outstanding adhesion promoters for metal contacts.

The composite layer can also be formed at least proportionally by reactive ion beam etching with oxygen. The ion bombardment gives rise to an intermixing of the metal surface which leads to a graded metal-oxide transition. Prior sputtering, for example of silicon, gives rise for example to a graded metal-metal oxide-silicon oxide transition as a basis for the composite with the LTCC ceramic.

Preferably, the ceramic circuit carrier and the composite layer are connected to one another by sintering at a temperature of between 840° C. and 930° C., in particular at approximately 900° C.

The invention therefore proposes process engineering solutions for the integration of highly thermally conductive heat sinks in LTCC. The cooling device and the heat sink can have any desired form, in principle, for the production process proposed. The configuration as a laterally extended shaped body having a homogeneous thickness is advantageous, however. Said shaped body can be areally smaller, larger or congruent with the multilayer ceramic circuit carrier. A metallic element can preferably be provided for the heat sink of the cooling device. In particular, the heat sink can be formed from copper, which has a very high thermal conductivity of approximately 400 W/m K. Other metals having adapted coefficients of thermal expansion are also possible, however, depending on the thickness ratio of the multilayer circuit carrier to the heat sink. By way of example, it is also possible to use copper-molybdenum composite metals having thermal conductivities in the region of approximately 200 W/m K. In order to compensate for slightly different expansion coefficients, the LTCC ceramic can be applied with the same thickness on both sides of the heat sink.

The method according to the invention proves to be particularly advantageous when the intention is to produce an electronic component module having at least two multilayer circuit carriers and a plurality and hence at least two integrated heat sinks. Particularly in the case of a multilayer system of this type it is particularly difficult to be able to ensure a sufficient composite structure by means of conventional technology. In particular by means of the method according to the invention it is also possible to produce such a multilayer system relatively simply and with little outlay and in particular to enable a plurality of heat sinks to be formed integrally. For precisely in the case of such complex structures, the bond between the circuit carriers and the composite layers and therefore also the heat sinks can be made possible automatically during the lamination and sintering of the individual layers of these circuit carriers. Consequently, it is no longer necessary to carry out respectively separate fitting, for example by soldering or adhesive bonding, in a complicated and cost-intensive manner after said production of the ceramic circuit carriers. In the case of integrated heat sinks, in particular, the method according to the invention can enable production to be considerably facilitated.

Furthermore, in the case of the electronic component module according to the invention, it is possible to achieve a purely passive heat dissipation without mobile substances, phase boundaries or phase transitions. Furthermore, a considerable increase in the thermal conductivity is possible. By way of example, this can be achieved by approximately ten-fold by comparison with thermal vias with the use of copper-molybdenum-copper laminates. A further increase in the thermal conductivity to up to 400 W/m K or higher can be made possible with the use of pure copper substrates or composite materials, for example on the basis of carbon nano fibers.

In addition to a high thermal conductivity, it is also possible to enable a stable material composite by means of alternating layers of electrical functional ceramic (ceramic circuit carriers) and highly thermally conductive material. Particularly when a heat sink is formed with laterally larger dimensions than a circuit carrier, it is also possible to enable simple mounting by means of screws in the region of the projecting heat sink.

Simple further processing by complete population of the module and a defined interface with the surroundings can likewise be achieved. In the case of a ceramic individual layer of the composite layer, a high electrical insulation in conjunction with high thermal coupling is achieved. Last but not least it is also possible to enable efficient heat dissipation from buried devices in the circuit carrier structure, in particular the LTCC ceramic.

### BRIEF DESCRIPTION OF THE DRAWING

Exemplary embodiments of the invention are explained in more detail below with reference to a schematic drawing. The single FIGURE shows a sectional illustration through an electronic component module according to the invention in accordance with an exemplary embodiment.

The electronic component module 1 comprises a first multilayer ceramic LTCC circuit carrier 2 and a second multilayer ceramic LTCC circuit carrier 3. These two circuit carriers 2 and 3 are arranged on opposite sides of a heat sink 4 assigned to a cooling device. In the exemplary embodiment, the heat sink 4 is therefore arranged integrally in the electronic component module 1 between the two circuit carriers 2 and 3. The heat sink 4 extends beyond the dimensions of the LTCC circuit carriers 2 and 3 on both sides in a lateral direction (x direction). Furthermore, holes 41 and 42 are formed in the heat sink 4, which are provided for fixing, in particular screwing, to further components or a housing.

A first composite layer 5 is formed between the upper LTCC circuit carrier 2 and the heat sink 4, which is formed from copper in the exemplary embodiment, said first composite layer connecting said first circuit carrier 2 to the heat sink 4 in a mechanically stable manner. A composite layer 6 is likewise formed in a corresponding manner between the heat sink 4 and the second LTCC circuit carrier 3. Both composite layers 5 and 6 are formed for reactive connection to the ceramic LTCC circuit carriers 2 and 3. This means that the bond between the composite layer 5 and the first circuit carrier 2 and the bond between the second composite layer 6 and the second circuit carrier 3 are also formed during the LTCC process for connecting the respective individual layers of the circuit carriers 2 and 3.

In the exemplary embodiment, the composite layers 5 and 6 are in each case formed over the whole area between the heat sink 4 and the respective circuit carrier 2 and 3. Furthermore, said composite layers 5 and 6 extend essentially over the entire surface of the heat sink 4 in a lateral direction. It can also be provided that the composite layers 5 and 6 are in each case formed only in regions. In particular, the composite layers 5 and 6 are formed at those locations at which the greatest amount of heat is generated on account of the arrangement of electronic devices in the respective circuit carriers 2 and 3. As a result of such targeted local formation of the composite layers 5 and 6, heat can then also be transported away in the best possible manner. Heat is transported away in this manner laterally in the exemplary embodiment shown.

The electronic component module 1 shown in the FIGURE is produced in such a way that firstly the composite layers 5 and are applied to the heat sink 4 on both sides. Various configurations can be provided depending on how said composite layers are intended to be formed. These configurations are mentioned in the general part of the description. In principle, any desired combination of the various embodiments of a composite layer mentioned there can also be provided.

After said composite layers 5 and 6 have been applied on the heat sink 4, the multilayer circuit carriers 2 and 3 are subsequently formed in an LTCC method. At the same time, during this method, in which the individual layers of the circuit carriers 2 and 3 are laminated onto one another and then sintered at a temperature of approximately 900° C., the bond between the composite layer 5 and the circuit carrier 2, on the one hand, and the composite layer 6 and the second circuit carrier 3, on the other hand, is also formed reactively.

With the completion of the circuit carriers 2 and 3 by means of the LTCC process, the complete electronic component module 1 and in particular the bond between the composite layers 5 and 6 and the circuit carriers 2 and 3, respectively, are also already formed completely according to the invention.

1. An electronic component module comprising:
at least one multilayer ceramic circuit carrier;
at least one cooling device comprising at least one heat sink; and
a composite layer arranged at least in regions between the ceramic circuit carrier and the cooling device, said composite layer being formed for reactive connection to the ceramic circuit carrier during a primary process and for connection to the cooling device.

2. The electronic component module as claimed in claim 1, wherein
the composite layer is formed over the whole area between the circuit carrier and the cooling device.

3. The electronic component module as claimed in claim 1, wherein
the cooling device is formed for lateral heat dissipation and the heat sink extends laterally beyond the dimensions of the circuit carrier at least at one side.

4. The electronic component module as claimed in claim 1, wherein
the primary process is an LTCC process for connecting the individual layers of the ceramic circuit carrier.

5. The electronic component module as claimed claim 1, wherein
the composite layer is formed at least as a monolayer, component-free and line-free LTCC film.

6. The electronic component module as claimed in claim 1, wherein
the composite layer is formed at least proportionally from glass.

7. The electronic component module as claimed claim 1, wherein
the composite layer is formed at least proportionally from nanocrystalline material.

8. The electronic component module as claimed claim 1, wherein
the composite layer is formed at least proportionally from ceramic material.

9. The electronic component module as claimed in claim 1, wherein
the composite layer is formed at least proportionally from a reactive metal.

10. The electronic component module as claimed in claim 1, wherein
the bond between the circuit carrier and the composite layer is formed by a sintering process at a temperature of between 840° C. and 930° C.

11. The electronic component module as claimed in claim 1, wherein
at least one cooling device is formed integrally between two multilayer circuit carriers.

12. A method for producing an electronic component module comprising:
connecting at least one ceramic multilayer circuit carrier to a cooling device comprising at least one heat sink; and,
forming a composite layer for connecting the at least one ceramic multilayer circuit carrier to the cooling device at least in regions between the ceramic circuit carrier and the cooling device, the composite layer being reactively connected to the circuit carrier during a primary process.

13. The method as claimed in claim 12,
the circuit carrier is formed as a ceramic LTCC circuit carrier and the composite layer is connected to the circuit carrier during an LTCC process as the primary process.

14. The method as claimed in claim 12, wherein,
the composite layer is formed prior to the formation of the multilayer circuit carrier on the cooling device.

15. The method as claimed in claim 12, wherein
at least one monolayer, component-free and line-free LTCC film is formed as the composite layer.

16. The method as claimed in claim 12, wherein
the composite layer is formed at least proportionally from glass, is applied in particular by screen printing and is subsequently thermally treated.

17. The method as claimed in claim 12, wherein,
the composite layer is formed at least proportionally from nanocrystalline material, and is applied in particular by screen printing.

18. The method as claimed in claim 12, wherein
the composite layer is formed at least proportionally from a ceramic material, and is applied by sputtering in a low-temperature method.

19. The method as claimed in claim 12, wherein
the composite layer is formed at least proportionally by a coating with reactive metals.

20. The method as claimed in claim 12, wherein
the composite layer is produced at least proportionally by reactive ion beam etching with oxygen of the metallically formed heat sink.

21. The method as claimed in claim 20, wherein
silicon is applied by sputtering prior to the ion beam etching.

22. The method as claimed in claim 12, wherein
the circuit carrier and the composite layer are connected by sintering at a temperature of between 840° C. and 930° C.
